(19) United States
(12) Patent Application Publication
(10) Pub. No.: US 2024/0427233 A1
(43) Pub. Date: Dec. 26, 2024

(54) IMPRINT APPARATUS, IMPRINT METHOD, AND METHOD OF MANUFACTURING SEMICONDUCTOR DEVICE

(71) Applicant: Kioxia Corporation, Tokyo (JP)

(72) Inventors: Shunsuke HONDA, Yokkaichi Mie (JP); Masayuki HATANO, Yokohama Kanagawa (JP)

(73) Assignee: Kioxia Corporation, Tokyo (JP)

(21) Appl. No.: 18/743,571

(22) Filed: Jun. 14, 2024

(30) Foreign Application Priority Data
Jun. 21, 2023 (JP) 2023-101363

(51) Int. Cl. G03F 7/00

(52) U.S. Cl. CPC G03F 7/0002; G03F 7/70141

(57) ABSTRACT

An imprint apparatus: a stage having a face on which an object is placed, the object having a first surface; a dropping device configured to drop a droplet of a photocurable resin in a first direction intersecting with the face; a irradiation device configured to irradiate a first light in a second direction intersecting with the first direction; a holder configured to hold a template having a second surface, the second surface having a pattern; an exposure device configured to irradiate a second light in a third direction intersecting with the face; and a control device configured to drive the dropping device and the irradiation device and control selecting whether to irradiate the first light to the droplet according to a position where the droplet is to be dropped on the first surface.

### CROSS-REFERENCE TO RELATED APPLICATION

This application is based upon and claims the benefit of priority from Japanese Patent Application No. 2023-101363, filed on Jun. 21, 2023; the entire contents of which are incorporated herein by reference.

### FIELD

Embodiments relate to an imprint apparatus, an imprint method, and a method of manufacturing a semiconductor device.

### BACKGROUND

A known example method of manufacturing a semiconductor device, enables forming a finer pattern applying the imprint technology with nanoimprint lithography (NIL).

### BRIEF DESCRIPTION OF THE DRAWINGS

FIG. 1 is a schematic view illustrating an example of an imprint apparatus in an embodiment.

FIG. 2 is a plan schematic view for explaining an example of an object 10 in an embodiment.

FIG. 3 is a perspective schematic view for explaining a structure example of a template in an embodiment.

FIG. 4 is a cross-sectional schematic view for explaining the structure example of the template in an embodiment.

FIG. 5 is a flowchart for explaining an example of an imprint method in an embodiment.

FIG. 6 is a schematic view for explaining an example of a dropping step S5 in an embodiment.

FIG. 7 is a schematic view for explaining the example of the dropping step S5 in an embodiment.

FIG. 8 is a schematic view for explaining the example of the dropping step S5 in an embodiment.

FIG. 9 is a schematic view for explaining the example of the dropping step S5 in an embodiment.

FIG. 10 is a schematic view for explaining a molding process in an imprint method in an embodiment.

FIG. 11 is a schematic view for explaining the molding process in the imprint method in the embodiment.

FIG. 12 is a schematic view for explaining a molding process without forming a treated droplet 20a.

FIG. 13 is a schematic view for explaining the molding process without forming the treated droplet 20a.

FIG. 14 is a schematic view for explaining a molding process with that an amount of dropping an imprint material is few.

FIG. 15 is a schematic view for explaining the molding process with that an amount of dropping an imprint material is few.

FIG. 16 is a schematic view for explaining an example of a curing step S8 in an embodiment

FIG. 17 is a schematic view for explaining an example of a template release step S9 in an embodiment.

FIG. 18 is a schematic view illustrating a first further example of the imprint apparatus in an embodiment.

FIG. 19 is a schematic view illustrating a second further example of the imprint apparatus in an embodiment.

FIG. 20 is a cross-sectional schematic view for explaining an example of a method of manufacturing a semiconductor device.

FIG. 21 is a cross-sectional schematic view for explaining the example of the method of manufacturing the semiconductor device in an embodiment.

### DETAILED DESCRIPTION

An imprint apparatus in an embodiment includes: a stage having a face on which an object is placed, the object having a first surface; a dropping device configured to drop a droplet of a photocurable resin in a first direction intersecting with the face; a irradiation device configured to irradiate a first light in a second direction intersecting with the first direction; a holder configured to hold a template having a second surface, the second surface having a pattern; an exposure device configured to irradiate a second light in a third direction intersecting with the face; and a control device configured to drive the dropping device and the irradiation device and control selecting whether to irradiate the first light to the droplet according to a position where the droplet is to be dropped on the first surface.

Embodiments will be hereinafter explained with reference to the drawings. A relation between the thickness and planar dimension of each of components illustrated in the drawings, a thickness ratio among the components, and so on may be different from actual ones. In the embodiments, substantially the same components are denoted by the same reference signs and an explanation thereof is omitted where appropriate.

A method of forming a pattern using NIL, includes pressing an imprint material on an object by a template to mold the imprint material, and then curing the molded imprint material and transfer a device pattern of the template to a cured layer of the imprint material. Known example methods of curing the imprint material, include heating the imprint material to cure the imprint material and irradiating a light to the imprint material to cure the imprint material.

Know example methods of supplying the imprint material onto the object, include a spin coating method and an inkjet method. The spin coating method includes applying the imprint material on the object and rotating the object. The inkjet method includes dropping a droplet of the imprint material onto the object using inkjet. The following embodiments include explaining an imprint apparatus and an imprint method using the inkjet method.

### (Imprint Apparatus)

FIG. 1 is a schematic view illustrating an example of the imprint apparatus. FIG. 1 illustrates an example configuration of an imprint apparatus 100. The imprint apparatus 100 has a stage 1, a dropping device 2, a irradiation device 3, a control device 4, a holder 5, an exposure device 6, and a control device 7. FIG. 1 indicates an X-axis, a Y-axis, and a Z-axis. The X-axis, the Y-axis, and the Z-axis perpendicularly intersect with one another.

The stage 1 can hold an object (a workpiece) 10 for imprinting. The stage 1 has a face 1a for placing the object 10. The face 1a is provided, for example, intersecting with the Z-axis and along an X-Y plane. The stage 1 is provided, for example, in a chamber of the imprint apparatus 100. The imprint apparatus 100 may have an electrostatic chuck for holding the object 10 on the face 1a of the stage 1. The object 10 may be loaded into the treatment chamber of the imprint apparatus 100 by a carrier device and be unloaded from the treatment chamber by the carrier device.

The dropping device 2 can drop a droplet 20 onto the object 10, the droplet 20 containing the imprint material. The dropping device 2 has, for example, a nozzle 21 for dropping the droplet 20. The droplet 20 is dropped, for example, in a Z-axis direction. The nozzle 21 may be connected to a supply source of the imprint material.

The imprint material is, for example, a photocurable resin for forming an etching mask. Examples of the photocurable resin include an ultraviolet curable resin such as a photoresist.

The irradiation device 3 can irradiate light 30. The irradiation device 3 has, for example, a light source which can irradiate the light 30. Examples of the light 30 include ultraviolet light. Examples of the light source include a mercury lamp. The light 30 is irradiated to the dropping droplet 20 (the droplet 20 during dropping) in a direction intersecting with a dropping direction (for example, the Z-axis direction) of the droplet 20, for example. The light 30 may be irradiated to the dropping droplet 20 in a direction perpendicular to the Z-axis direction. The Z-axis direction may be perpendicular to a surface of the object 10.

The control device 4 can control the dropping device 2 and the irradiation device 3. The control device 4 has, for example, hardware having an arithmetic unit such as a processor. The operations of the imprint apparatus 100 may be held as an operating program in a computer-readable recording medium such as a memory, and the operating program stored in the recording medium may be read as appropriate by the hardware to execute each operation. The control device 4 may further have at least one drive device of a drive device for driving the dropping device 2 and a drive device for driving the irradiation device 3.

The holder 5 can hold a template 50. The material of the template 50 is not particularly limited. When the photocurable resin is used as the imprint material, the template 50 formed from a light transparent material such as quartz glass enables the light to reach the imprint material therethrough. The holder 5 may have an electrostatic chuck for holding the template 50. The holder 5 is vertically movable, for example, along the Z-axis direction.

The exposure device 6 can irradiate light 60 to a layer formed on the object 10, the layer containing the imprint material. The exposure device 6 has, for example, a light source which irradiates the light to the object 10. Examples of the light 60 include ultraviolet light. Examples of the light source include a mercury lamp. The light 60 is irradiated from a position across the droplet 20 from the object 10 along a direction not intersecting with the direction (for example, the Z-axis direction) of dropping the droplet 20, in other words, a direction intersecting with a direction (for example, the Z-axis direction) of irradiating the light 30 to the droplet 20. The light 60 may be irradiated to the droplet 20 in a direction perpendicular to the direction of irradiating the light 30 to the dropping droplet 20.

The light 30 and the light 60 may have different wavelengths and different illuminances.

The control device 7 can control the stage 1, the holder 5, and the exposure device 6. The control device 7 has, for example, hardware having an arithmetic unit such as a processor. The operations of the imprint apparatus 100 may be held as an operating program in a computer-readable recording medium such as a memory, and the operating program stored in the recording medium may be read as appropriate by the hardware to execute each operation. The control device 7 may further have at least one drive device of a drive device for driving the stage 1, a drive device for driving the holder 5, and a drive device for driving the exposure device 6. The control device 7 and the control device 4 may be composed of one control device.

### (Object 10)

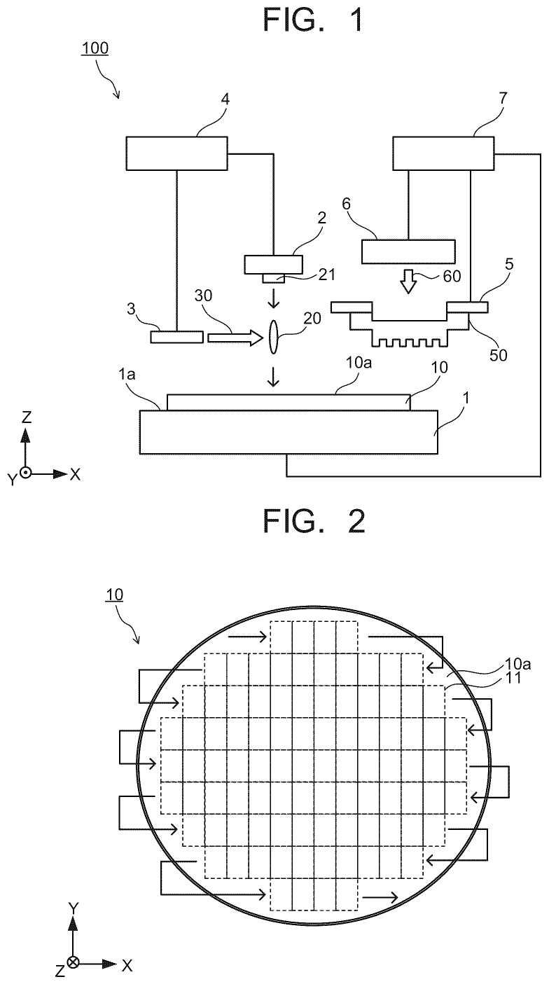

FIG. 2 is a plan schematic view for explaining an example of the object. FIG. 2 illustrates the object 10. The object 10 has a surface 10a. The surface 10a has a plane intersecting with the Z-axis direction, and is arranged on a surface of the stage 1 opposite to the face 1a. The thickness direction of the object 10 corresponds to, for example, the Z-axis direction.

The surface 10a has a shot region 11. The shot region 11 is a unit region where a pattern is transferred at once by pressing the template 50 against the imprint material at one time imprint. FIG. 2 illustrates a plurality of the shot regions 11. The shot regions 11 are arrayed along the X-Y plane. The surface 10a may have at least one space between the shot regions 11.

Examples of the object 10 include a stack formed by stacking films onto a substrate such as a silicon wafer. Examples of the stack include a device wafer (a semiconductor substrate) in the process of manufacturing a semiconductor device. Examples of the semiconductor device include a semiconductor memory device such as a NAND flash memory, an electrical device having a fine structure such as a microelectromechanical system (MEMS), and a magnetic recording medium. The configuration of the object 10 is not limited to the aforementioned configurations.

### (Template 50)

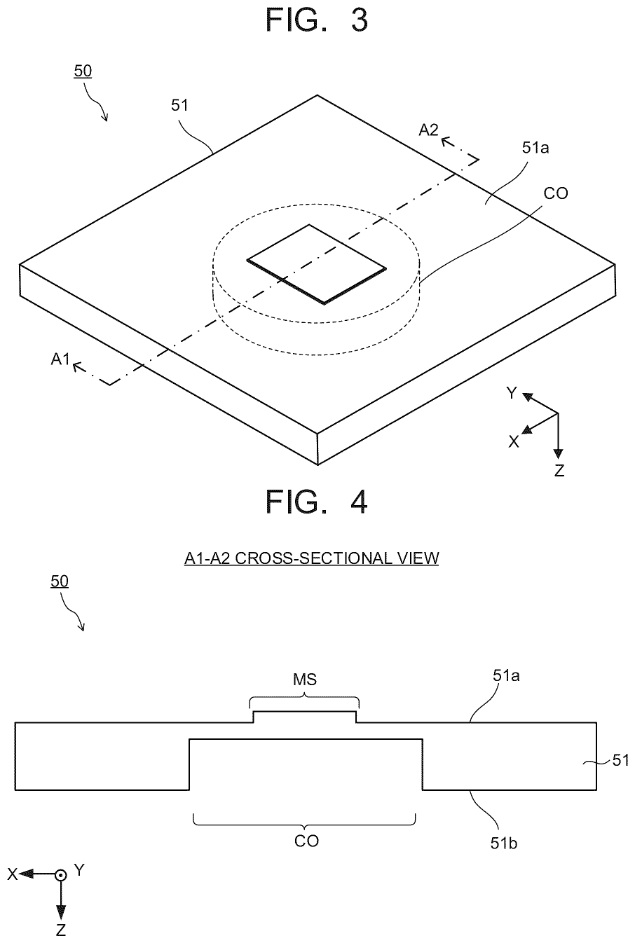

FIG. 3 is a perspective schematic view for explaining a structure example of the template. FIG. 4 is a cross-sectional schematic view for explaining the structure example of the template. FIG. 3 and FIG. 4 indicate an X-axis, a Y-axis, and a Z-axis. FIG. 4 partly illustrates the cross section at line segment A1-A2 illustrated in FIG. 3.

The template 50 has a substrate 51. The substrate 51 contains a material such as quartz glass, which is transparent to the light 60. The substrate 51 has a surface 51a and a surface 51b, the surface 51a having a mesa MS, and the surface 51b having a depression CO. The surface 51a corresponds to a primary surface. The mesa MS is a region corresponding to one of the shot regions 11, and a region where the device pattern is to be formed. The planar shape of the mesa MS is not particularly limited. For example, the planar shape of the mesa MS may be a rectangular shape. A plane area of the mesa MS may be the same as the plane area of one shot region 11.

### (Imprint Method)

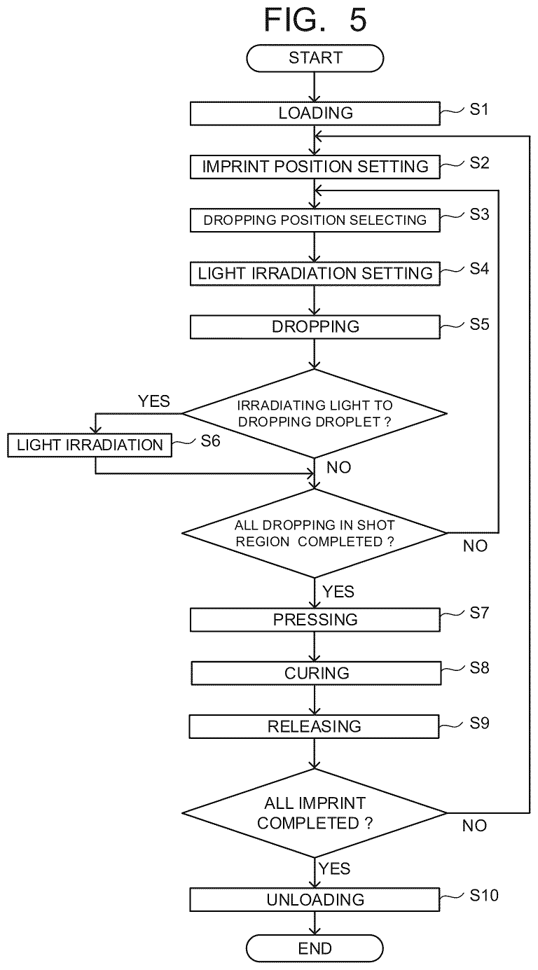

FIG. 5 is a flowchart for explaining an example of the imprint method. The example of the imprint method includes a loading step S1, an imprint position selection step S2, a dropping position selection step S3, a light irradiation setting step S4, a dropping step S5, a light irradiation step S6, a pressing step S7, a curing step S8, a template release step S9, and a unloading step S10. These steps can be performed in order, for example, using the imprint apparatus 100 illustrated in FIG. 1.

### [Loading Step S1]

The loading step S1 includes loading the object 10 into the imprint apparatus 100. The object 10 can be loaded into the treatment chamber of the imprint apparatus 100, for example, by the carrier device. The object 10 is placed on the stage 1.

### [Imprint Position Selection Step S2]

The imprint position selection step S2 includes selecting the shot region 11 to be imprinted from the shot regions 11 on the surface 10a of the object 10. The shot region 11 to be imprinted can be selected, for example, by driving the stage 1 through the control device 7 to move the stage 1 along the X-Y plane.

### [Dropping Position Selection Step S3]

The dropping position selection step S3 includes selecting a position (a dropping position) where the droplet 20 is dropped in the selected shot region 11. The dropping position can be selected by the following method that includes: recording in advance data indicating the dropping position of each droplet 20 on the shot region 11 in the recording medium of the control device 7; and reading as appropriate the data indicating each dropping position by the hardware; driving the stage 1 through the control device 7 to move the stage 1 based on the data indicating the dropping position read from the recording medium of the control device 7; and aligning the position of the nozzle 21 and the corresponding dropping position on the selected shot region 11, for example.

### [Light Irradiation Setting Step S4]

The light irradiation setting step S4 includes setting whether the irradiation of the light 30 toward the droplet 20 to be dropped onto the selected dropping position is necessary or not. The necessity of the irradiation of the light 30 can be decided, for example, by recording in advance data indicating the necessity of the light irradiation corresponding to the dropping position of each droplet 20 on the shot region 11 in the recording medium of the control device 4, and reading as appropriate the data corresponding to each dropping position by the hardware. The data indicating the necessity of the light irradiation corresponding to the dropping position of each droplet 20 can be generated by referring to the data on the dropping position of each droplet 20 and the data on the pattern of the template 50 through the control device 4. If the irradiation of the light 30 is necessary, the irradiation conditions such as the wavelength and the illuminance of the light 30 may further be set. The irradiation conditions can be set, for example, by recording in advance data indicating the light irradiation conditions corresponding to the dropping position where the irradiation of the light 30 is necessary in the recording medium of the control device 4, and reading as appropriate the data corresponding to each dropping position by the hardware.

### [Dropping Step S5]

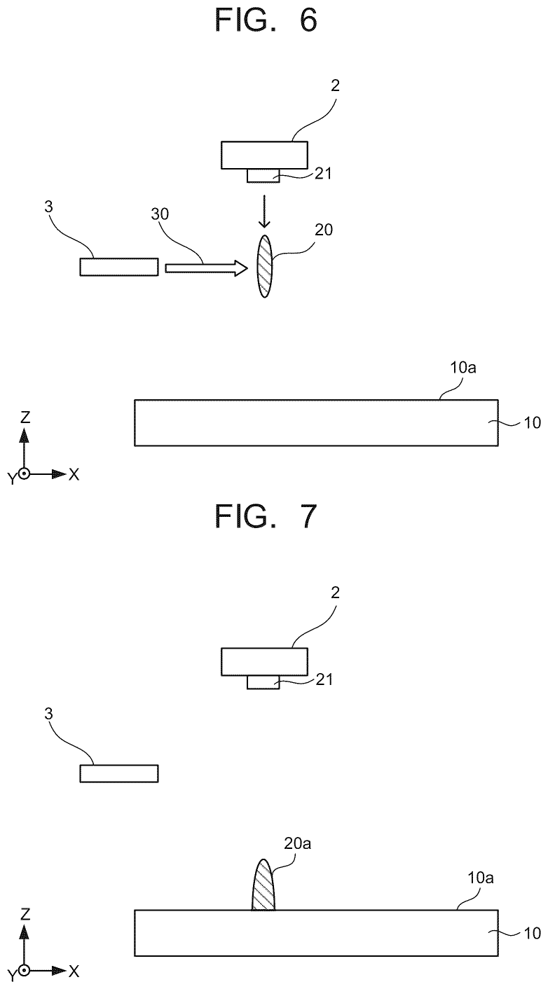

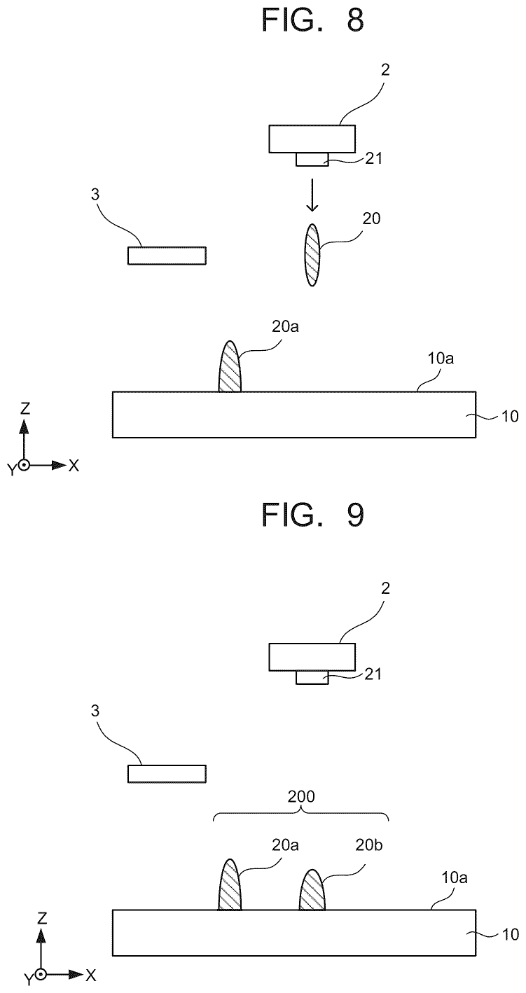

FIG. 6, FIG. 7, FIG. 8, and FIG. 9 are schematic views for explaining an example of the dropping step S5. FIG. 6, FIG. 7, FIG. 8, and FIG. 9 partly illustrate the X-Z cross section of the object 10.

The dropping step S5 includes dropping the droplet 20. The droplet 20 can be dropped, for example, by driving the dropping device 2 through the control device 4 to drop the droplet of the imprint material from the dropping device 2.

When the light irradiation setting step S4 sets that the irradiation of the light 30 is necessary to the droplet 20 corresponding to the dropping position, the light irradiation step S6 is performed. The light irradiation step S6 includes irradiating the light 30 to the dropping droplet 20. The light 30 can be irradiated to the dropping droplet 20 from the irradiation device 3 in the direction intersecting with the Z-axis direction as illustrated in FIG. 6, for example, by driving the irradiation device 3 through the control device 4. Since the dropping droplet 20 passes through the light 30 irradiated in the direction intersecting with the Z-axis direction to receive the light 30 for a predetermined period, the light 30 is irradiated to the droplet 20 for a period shorter than the period of irradiating the light 60 in the curing step S8 explained later, for example. The irradiation of the light 30 can increase the viscosity of the dropped droplet 20 without the dropped droplet 20 being not completely cured and with the dropped droplet 20 maintaining the fluidity. The droplet 20 treated by the irradiation of the light 30 can be regarded as liquid. The irradiation of the light 30 from the irradiation device 3 is stopped after the treatment of the selected droplet 20 by driving the irradiation device 3 through the control device 4. The droplet 20 treated by the irradiation of the light 30 defines a treated droplet 20a and reaches the surface of the object 10 as illustrated in FIG. 7. The viscosity of the treated droplet 20a can be adjusted, for example, by adjusting the wavelength and the illuminance of the light 30 through the irradiation device 3.

On the other hand, when the light irradiation setting step S4 sets that the irradiation of the light 30 to the droplet 20 corresponding to the dropping position is unnecessary, the light irradiation step S6 is not performed. Thus, the light 30 is not irradiated to the dropping droplet 20. In this case, the droplet 20 is dropped to the surface 10a without receiving the light 30 as illustrated in FIG. 8. The irradiation of the light 30 can be stopped by driving the irradiation device 3 through the control device 4. The droplet 20 not treated by the irradiation of the light 30 defines an untreated droplet 20b and reaches the surface of the object 10 as illustrated in FIG. 9. The viscosity of the treated droplet 20a is higher than the viscosity of the untreated droplet 20b, for example, under an environment at a temperature of 25° C.

The diameter of the treated droplet 20a is smaller than the diameter of the untreated droplet 20b. The height of the treated droplet 20a is larger than the height of the untreated droplet 20b. The size of each of the treated droplet 20a and the untreated droplet 20b can be determined, for example, according to the size or the dropping amount of the nozzle 21 of the dropping device 2.

Thereafter, if the dropping of all of the droplets 20 has not been completed in one shot region 11, the flow returns to the dropping position selection step S3, in which the next dropping position on the selected shot region 11 is selected, the light irradiation setting step S4 and the dropping step S5 are performed in order, and then the light irradiation step S6 is performed as necessary. These steps can form a dropped resin 200 onto the surface 10a, the dropped resin 200 being defined by droplets including the treated droplet 20a and the untreated droplet 20b. After completion of the dropping of all of the droplets 20 on the selected shot region 11, the pressing step S7 is then performed.

### [Pressing Step S7]

The pressing step S7 includes pressing the template 50 on the dropped resin 200 to mold the dropped resin 200. The template 50 can be pressed, for example, by driving the holder 5 through the control device 7 to move the template 50 along the Z-axis direction to the dropped resin 200. The dropped resin 200 is formed according to the pattern of the template 50.

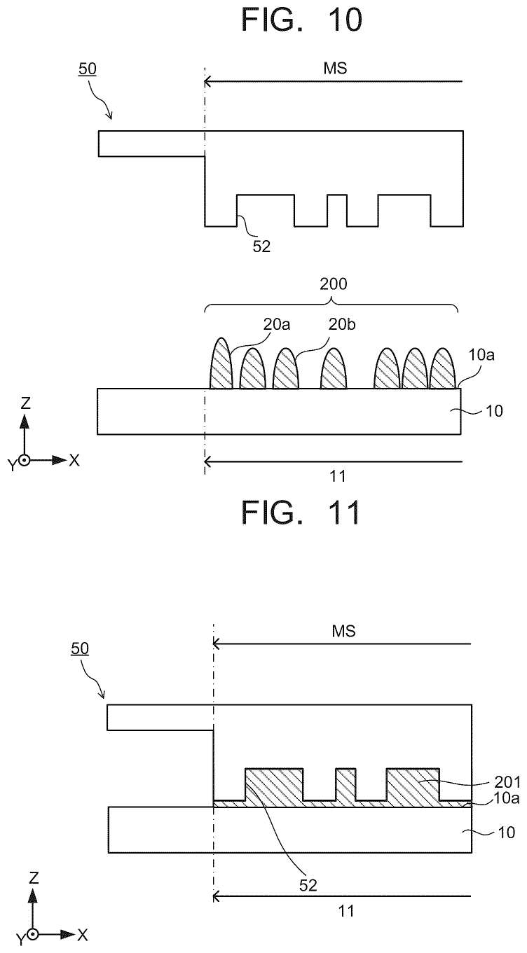

FIG. 10 and FIG. 11 are schematic views for explaining a molding process in the imprint method in the embodiments. FIG. 10 and FIG. 11 partly illustrate the template 50 having the mesa MS and the object 10. The periphery of the shot region 11 overlaps the periphery of the mesa MS in the Z-axis direction. The template 50 has a device pattern having a depression 52. FIG. 10 and FIG. 11 shows a plurality of the depressions 52. In the imprint method in the embodiment, the treated droplet 20a on the shot region 11 is positioned outside the untreated droplet 20b on the shot region 11 so that the treated droplet 20a is closer to the periphery of the shot region 11 than the untreated droplet 20b is. The treated droplet 20a is formed, for example, adjacent to the periphery of the shot region 11. The numbers of the treated droplets 20a and the untreated droplets 20b are not limited to the numbers illustrated in FIG. 10 and FIG. 11. As illustrated in FIG. 10, when the template 50 is pressed against the dropped resin 200, the treated droplet 20a and the untreated droplet 20b are molded and come into contact with the depressions 52 to enable forming a layer 201 as illustrated in FIG. 11.

In the inkjet NIL, the droplet 20 of the imprint material has a predetermined volume. Therefore, the amount of the imprint material necessary for transferring the pattern of the template 50 can be adjusted by controlling the dropping position of the droplet 20 or the pitch between the droplets 20.

However, the control of only at least one of the dropping position of the droplet 20 and the pitch between the droplets 20, cannot sufficiently adjust the amount of the imprint material to possibly result in that the imprint material partly extends outside the shot region 11 from the periphery of the shot region 11, for example. Particularly, when the device pattern has a pattern region adjacent to the periphery of the shot region 11 to need a large amount of the imprint material, the amount of the imprint material extending outside the shot region 11 also increases, so that the prevention of the extension of the imprint material is difficult.

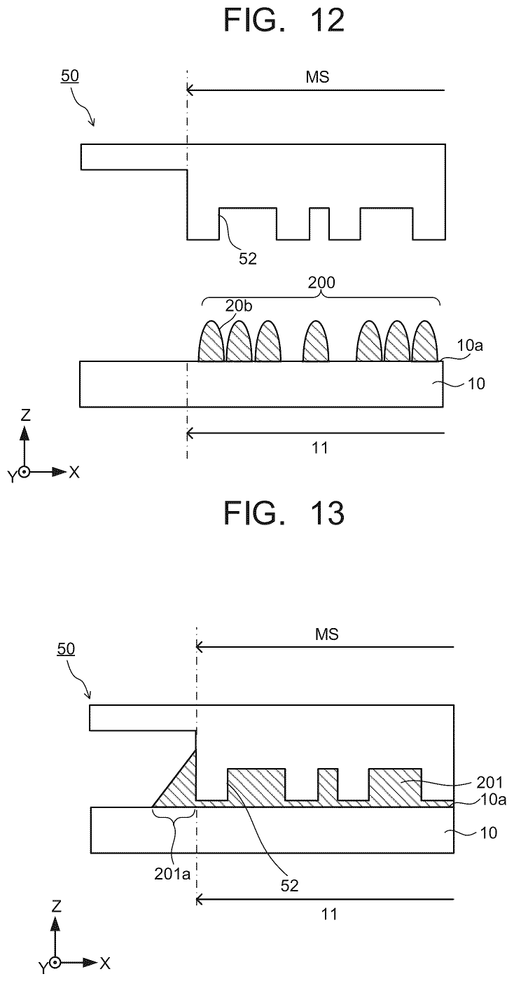

FIG. 12 and FIG. 13 are schematic views for explaining a molding process without forming the treated droplet 20a. FIG. 12 and FIG. 13 partly illustrate the template 50 and the object 10. The periphery of the shot region 11 overlaps the periphery of the mesa MS in the Z-axis direction.

Assuming that any treated droplet 20a is not formed, the dropped resin 200 formed on the surface 10a includes a plurality of the untreated droplets 20b and does not include any treated droplet 20a as illustrated in FIG. 12. Therefore, the untreated droplet 20b is formed also on or adjacent to the periphery of the shot region 11. When the template 50 is pressed against the dropped resin 200 not including any treated droplet 20a, the imprint material is likely to extend outside the overlap between the shot region 11 and the mesa MS to form a layer 201 with an extension region 201a as illustrated in FIG. 13. The extension region 201a causes forming an unnecessary pattern onto the cured layer 201. Further, the extension region 201a is likely to be formed near a region where the droplets 20 are closely dropped on the shot region 11, namely, a region where the pitch between the untreated droplets 20b on the shot region 11 is small. For example, the droplets 20 need to be closely dropped on a portion provided on the shot region 11 and overlapping the depression 52 (the large depression 52) large in width and depth, because the large depression 52 needs to the large amount of the imprint material for filling the large depression 52.

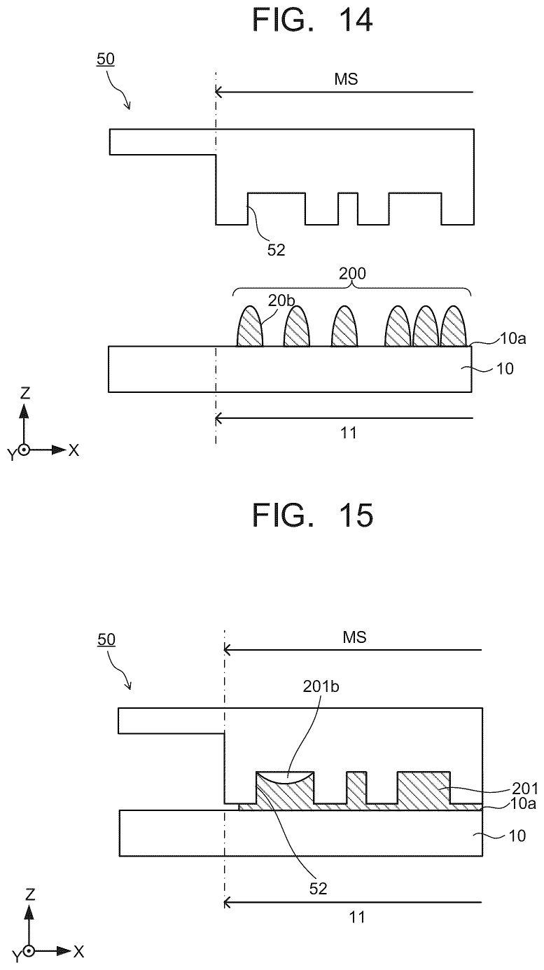

Conceivable methods of preventing the formation of the extension region 201a, include reducing the amount of dropping the imprint material. FIG. 14 and FIG. 15 are schematic views for explaining a molding process with that the amount of dropping the imprint material is few. FIG. 14 and FIG. 15 partly illustrate the template 50 and the object 10. The periphery of the shot region 11 overlaps the periphery of the mesa MS in the Z-axis direction. Assuming that the amount of the imprint material is reduced, the dropped resin 200 formed on the surface 10a includes a plurality of the untreated droplets 20b less in number than the untreated droplets 20b illustrated in FIG. 12 and does not include any treated droplet 20a, as illustrated in FIG. 14. When the template 50 is pressed against the dropped resin 200 not including any treated droplet 20a, the depressions 52 is insufficiently filled with the imprint material to easily generate a void 201b, as illustrated in FIG. 15. The void 201b causes a difference between a measured pattern dimension of the cured layer 201 and a desired pattern dimension of the cured layer 201. Since the imprint material concentrically spreads at a constant speed on the shot region 11, the void 201b is likely to be formed in a space surrounded by the imprint material, for example.

In contrast to the above, the device and the method in the embodiment can select whether to irradiate the light 30 to the dropping droplet 20 according to the dropping position, and irradiate the light 30, for example, to the droplet 20 to be dropped to a region where the imprint material is likely to extend to increase the viscosity of the droplet 20, to form the dropped resin 200 with a viscosity distribution and to locally change the speed at which the imprint material spreads by the pressing step S7. For example, the light 30 is irradiated to the droplet 20 to be dropped to increase the viscosity of the droplet 20 in a region located on the periphery of the shot region 11 and a region where droplets 20 are closely dropped (a region where the pitch between the droplets 20 is smaller than a reference value). This can reduce the extension of imprint material. Therefore, a pattern having a desired dimension can be precisely formed. Further, the irradiation of the light 30 to the dropping droplet 20 enables adjusting the viscosity for each droplet 20, for example. This enables to more finely control the viscosity distribution of the droplet 20 as compared with the case of increasing the viscosity by exposing the region where the imprint material is likely to extend on the shot region 11 after dropping the droplets 20.

### [Curing Step S8]

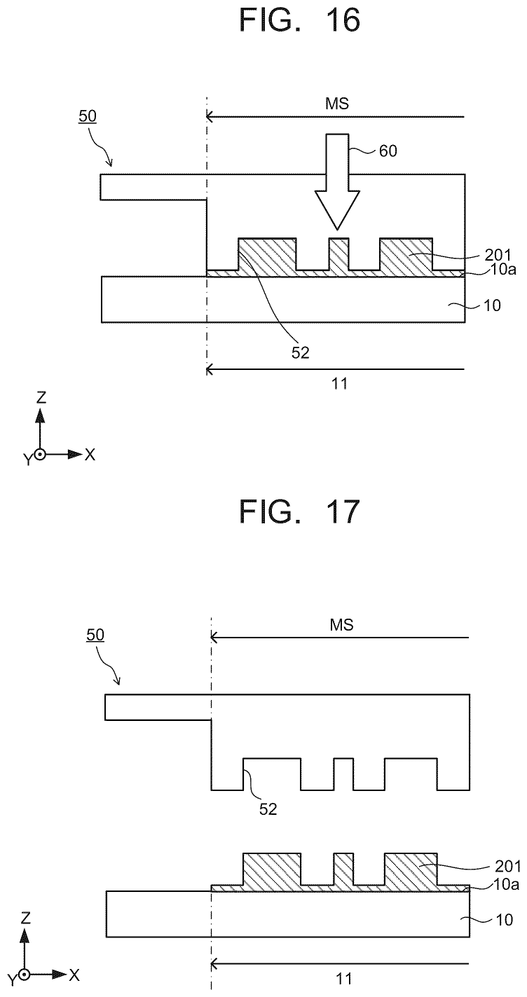

FIG. 16 is a schematic view for explaining an example of the curing step S8. FIG. 16 partly illustrates the X-Z cross section.

The curing step S8 includes irradiating the light 60 to the layer 200 to cure the layer 201. The light 60 can be irradiated to the layer 201 from the exposure device 6 through the template 50, for example, by driving the exposure device 6 through the control device 7. The light 60 is irradiated, for example, until the layer 201 is completely cured. Then, the irradiation of the light 60 is stopped, for example, by driving the exposure device 6 through the control device 7. The viscosity of the treated droplet 20a is lower than the viscosity of the layer 201 (the cured layer 201) after curing under an environment at a temperature of 25° C., for example.

### [Template Release Step S9]

FIG. 17 is a schematic view for explaining an example of the template release step S9. FIG. 17 partly illustrates the X-Z cross section of the object 10.

The template release step S9 includes releasing the template 50 from the cured layer 201 as illustrated in FIG. 17. The template 50 can be released from the cured layer 201 by driving the holder 5 through the control device 7 to move the template 50 away from the cured layer 201 in the Z-axis direction, for example.

The cured layer 201 has an inverted pattern of the pattern of the template 50, the inverted pattern being formed by transferring the pattern of the template 50 to the layer 201. The inverted pattern is not particularly limited. Examples of the inverted pattern include a fine pattern that includes wiring patterns.

Thereafter, when the imprint has not been completed in all of the shot regions 11, the flow returns to the imprint position selection step S2, the next shot region 11 is selected, the dropping position selection step S3, the light irradiation setting step S4, the dropping step S5, the light irradiation step S6, the pressing step S7, the curing step S8, and the template release step S9 are performed in order. Each shot region 11 is sequentially selected in the order along arrows in FIG. 2. After the imprint has been completed in all of the shot regions 11, the unloading step S10 is performed next.

### [Unloading Step S10]

The unloading step S10 includes unloading the object 10. The object 10 can be unloaded from the treatment chamber of the imprint apparatus 100 by the carrier device, for example. The above is the explanation of the imprint method.

### First Further Example of the Imprint Apparatus

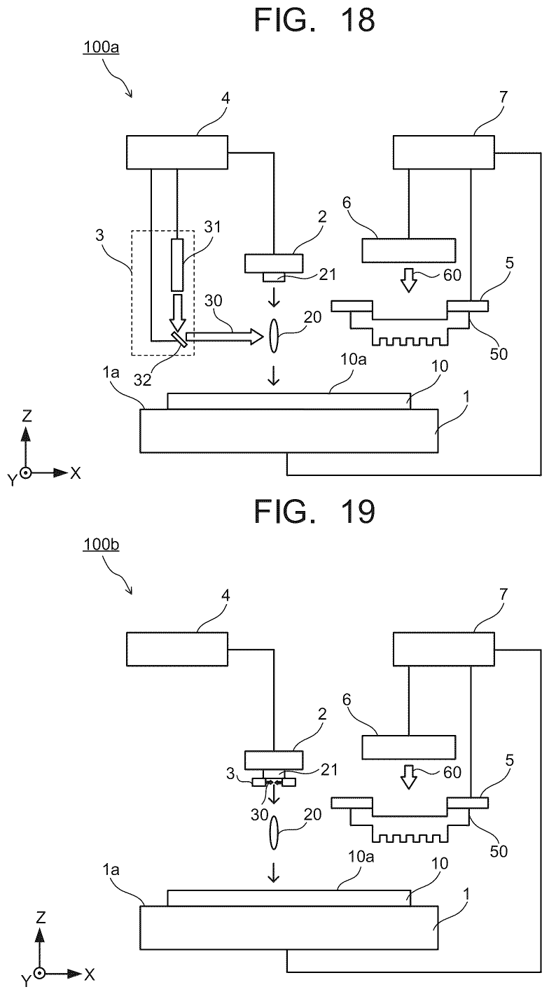

FIG. 18 is a schematic view illustrating a first further example of the imprint apparatus. FIG. 18 indicates an X-axis, a Y-axis, and a Z-axis. FIG. 18 shows an imprint apparatus 100 a.

The imprint apparatus 100a is different in configuration of the irradiation device 3 as compared with the imprint apparatus 100 illustrated in FIG. 1. Parts of the imprint apparatus 100a different from those of the imprint apparatus 100 will be explained below, and the explanation of FIG. 1 can be appropriately used for the other portions.

The irradiation device 3 has a light source 31 and an optical system 32. The light source 31 can emit the light 30, for example. The optical system 32 can control the irradiation conditions such as the incident angle of the light 30 to the droplet 20 and illuminance of the light 30 to the droplet 20. Examples of the optical system 32 include a light reflector such as a mirror, and an optical instrument such as a digital mirror device (DMD).

The first further example of the imprint apparatus includes the optical system 32 to enable changing the viscosity for each droplet 20 to which the light 30 is irradiated, for example. This can adjust the viscosity of the treated droplet 20a according to the pitch when a plurality of the treated droplets 20a is formed, for example.

### Second Further Example of the Imprint Apparatus

FIG. 19 is a schematic view illustrating a second further example of the imprint apparatus. FIG. 19 indicates an X-axis, a Y-axis, and a Z-axis. FIG. 19 shows an imprint apparatus 100b.

The imprint apparatus 100b is different in configuration of the irradiation device 3 provided in the dropping device 2 as compared with the imprint apparatus 100 illustrated in FIG. 1. Parts of the imprint apparatus 100b different from those of the imprint apparatus 100 will be explained below, and the explanation of FIG. 1 can be appropriately used for the other portions.

The irradiation device 3 is provided to surround the hole of the nozzle 21 of the dropping device 2 along the X-Y plane, for example. This enables to irradiate the light 30 to the droplet 20 to be dropped from the hole of the nozzle 21 from a direction intersecting with the Z-axis direction. The irradiation device 3 may be provided inside the dropping device 2.

The second further example of the imprint apparatus has the configuration that the irradiation device 3 is provided in the dropping device 2, to enable downsizing the imprint apparatus, for example.

### (A Method of Manufacturing a Semiconductor Device)

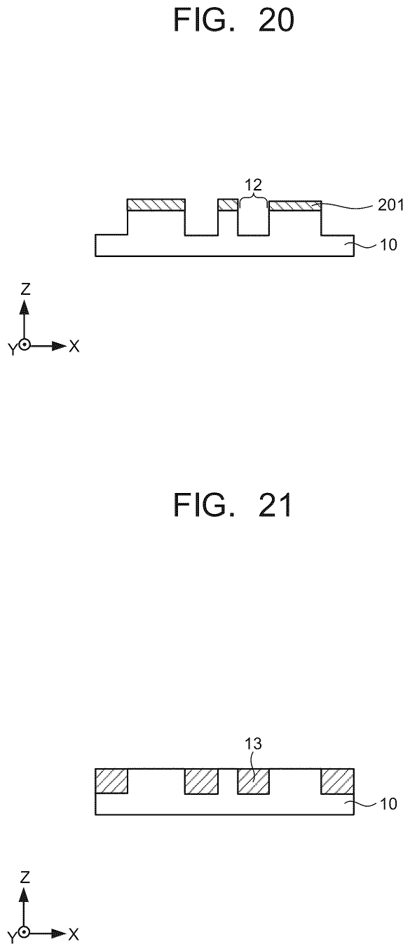

FIG. 20 and FIG. 21 are cross-sectional schematic views for explaining an example of the method of manufacturing a semiconductor device. The object 10 is partly processed using the cured layer 201 formed through the imprint apparatus and the imprint method in the embodiment, to have an inverted pattern having depressions 12, as illustrated in FIG. 20. The object 10 is partly processed by partly removing stacked layers constituting the object 10 by dry-etching, for example. The shape of the object 10 after processing is decided according to the shape of the device pattern.

Next, as illustrated in FIG. 21, a film (a film to be processed) is formed onto the object 10 and the film is processed to form a layer 13 in the depression 12. Examples of the layer 13 include a conductive layer containing a metal material. The layer 13 has, for example, a function as embedded wiring.

As explained above, the example method of manufacturing the semiconductor device in this embodiment can manufacture the semiconductor device by processing the object 10 through the etching using the imprint material cured layer formed through the imprint apparatus and the imprint method in the embodiment.

While certain embodiments of the present invention have been described above, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint apparatus comprising:
a stage having a face on which an object is placed, the object having a first surface;
a dropping device configured to drop a droplet of a photocurable resin in a first direction intersecting with the face;
a irradiation device configured to irradiate a first light in a second direction intersecting with the first direction;
a holder configured to hold a template having a second surface, the second surface having a pattern;
an exposure device configured to irradiate a second light in a third direction intersecting with the face; and
a control device configured to drive the dropping device and the irradiation device and control selecting whether to irradiate the first light to the droplet according to a position where the droplet is to be dropped on the first surface.

2. The imprint apparatus according to claim 1, wherein:
the first surface has a shot region;
the control device is configured to drive the dropping device and the irradiation device so as not to irradiate the first light to the dropping droplet when the position corresponds to a first position on the shot region; and
the control device is configured to drive the dropping device and the irradiation device so as to irradiate the first light to the dropping droplet when the position corresponds to a second position on the shot region, the second position being closer to an periphery of the shot region than the first position is.

3. The imprint apparatus according to claim 1, wherein
the irradiation device comprises:
a light source configured to emit the first light; and
an optical system configured to control the first light.

4. The imprint apparatus according to claim 1, wherein
the irradiation device is provided in the dropping device.

5. The imprint apparatus according to claim 1, wherein
the first direction is perpendicular to the second direction.

6. The imprint apparatus according to claim 1, wherein
the second light has a wavelength different from a wavelength of the first light.

7. An imprint method comprising:
dropping a first droplet of a photocurable resin and irradiating a first light to the dropping first droplet, to form a treated droplet of the first droplet on a first surface of an object;
dropping a second droplet of the photocurable resin without irradiating the first light to the dropping second droplet, to form an untreated droplet of the second droplet on the first surface;
pressing a pattern on a second surface of a template against a dropped resin having the treated droplet and the untreated droplet, to mold the dropped resin and thus form a layer of the photocurable resin;
irradiating a second light to the layer through the template to cure the layer and transfer the pattern to the layer; and
releasing the template from the cured layer with the transferred pattern, wherein
the treated droplet has a viscosity higher than a viscosity of the untreated droplet and lower than a viscosity of the cured layer.

8. The imprint method according to claim 7, wherein
a period of irradiating the first light to the first droplet is shorter than a period of irradiating the second light to the layer.

9. The imprint method according to claim 7, wherein:
the pattern has a depression; and
the pattern is pressed against the dropped resin to bring the treated droplet into contact with the depression.

10. The imprint method according to claim 7, wherein:
the first surface has a shot region; and
the treated droplet is formed adjacent to a periphery of the shot region.

11. The imprint method according to claim 7, wherein:
the pattern includes a first depression and a second depression;
the second depression has a width larger than a width of the first depression; and
the pattern is pressed against the dropped resin to bring the untreated droplet into contact with the first depression and bring the treated droplet into contact with the second depression.

12. The imprint method according to claim 7, further comprising:
dropping a third droplet of the photocurable resin and irradiating the first light to the dropping third droplet, to form a second treated droplet of the third droplet adjacent to the treated droplet on the first surface; and
dropping a fourth droplet of the photocurable resin without irradiating the first light to the dropping fourth droplet, to form a second untreated droplet of the fourth droplet adjacent to the untreated droplet on the first surface, wherein:
the dropped resin further includes the second treated droplet and the second untreated droplet; and
a gap between the treated droplet and the second treated droplet is narrower than a gap between the untreated droplet and the second untreated droplet.

13. The imprint method according to claim 7, wherein:
the first light is irradiated in a second direction intersecting with a first direction perpendicular to the first surface; and
the second light is irradiated in a third direction intersecting with the first surface and intersecting with the second direction.

14. A method of manufacturing a semiconductor device, comprising:
dropping a first droplet of a photocurable resin and irradiating a first light to the dropping first droplet, to form a treated droplet of the first droplet on a first surface of an object;
dropping a second droplet of the photocurable resin without irradiating the first light to the dropping second droplet, to form an untreated droplet of the second droplet on the first surface;
pressing a pattern on a second surface of a template against dropped resin including the treated droplet and the untreated droplet, to mold the dropped resin and form a layer of the photocurable resin;
irradiating second light to the layer through the template to cure the layer and transfer the pattern to the layer;
releasing the template from the cured layer to which the pattern has been transferred; and
processing the object by etching using the layer, wherein
the treated droplet has a viscosity higher than a viscosity of the untreated droplet and lower than a viscosity of the cured layer.

15. The method according to claim 14, wherein
a period of irradiating the first light to the first droplet is shorter than a period of irradiating the second light to the layer.

16. The method according to claim 14, wherein:
the pattern has a depression; and
the pattern is pressed against the dropped resin to bring the treated droplet into contact with the depression.

17. The method according to claim 14, wherein:
the first surface has a shot region; and
the treated droplet is formed adjacent to a periphery of the shot region.

18. The method according to claim 14, wherein:
the pattern has a first depression and a second depression;
the second depression has a width larger than a width of the first depression; and
the pattern is pressed against the dropped resin to bring the untreated droplet into contact with the first depression and bring the treated droplet into contact with the second depression.

19. The method according to claim 14, further comprising:
dropping a third droplet of the photocurable resin and irradiating the first light to the dropping third droplet, to form a second treated droplet of the third droplet on the first surface, the second treated droplet being adjacent to the treated droplet; and
dropping a fourth droplet of the photocurable resin without irradiating the first light to the dropping fourth droplet, to form a second untreated droplet of the fourth droplet on the first surface, the second untreated droplet being adjacent to the untreated droplet, wherein:
the dropped resin further includes the second treated droplet and the second untreated droplet; and
a gap between the treated droplet and the second treated droplet is narrower than a gap between the untreated droplet and the second untreated droplet.

20. The method according to claim 14, wherein:
the first light is irradiated in a second direction intersecting with a first direction perpendicular to the first surface; and
the second light is irradiated in a third direction intersecting with the first surface and intersecting with the second direction.
